(19) United States
(12) Patent Application Publication
(10) Pub. No.: US 2013/0056601 A1
(43) Pub. Date: Mar. 7, 2013

(54) ADJUSTMENT MECHANISM FOR USE WITH MOUNTING SYSTEMS FOR AUDIO/VISUAL DEVICES OR THE LIKE

(71) Applicants: James M. Stemple, Marengo, IL (US); Grant Wylie, Plainfield, IL (US)

(72) Inventors: James M. Stemple, Marengo, IL (US); Grant Wylie, Plainfield, IL (US)

(73) Assignee: Peerless Industries, Inc.

(21) Appl. No.: 13/226,778

(22) Filed: Sep. 7, 2011

(51) Int. Cl. H05K 7/00; E05D 11/10; F16M 13/00

(52) U.S. Cl. 248/282.1; 248/289.11; 16/319; 16/322

(57) ABSTRACT

An adjustment mechanism for use in a mounting system comprising a first mounting portion configured to operatively connect to the audio/visual device and a second mounting portion configured to attach to the first mounting portion and to a mounting surface. The adjustment mechanism operatively connects the first mounting portion to the second mounting portion. The adjustment mechanism includes a housing with a bore formed therein, a clutch positioned within the housing, and a rotatable shaft positioned within the housing and being operatively connected to the first mounting portion. The shaft is configured to rotate within the bore relative to the housing. The shaft is rotatable within the bore in a first rotational direction through the clutch with a first torque, and the shaft is also rotatable within the bore in a second rotational direction through the clutch with a second torque.

### BACKGROUND

The present application relates generally to the field of mounting systems for audio/visual devices. More specifically, the present application relates to mounting systems including adjustment mechanisms that provide improved variable adjustability of the mounted device.

### SUMMARY

One embodiment of the invention relates to a mounting system for supporting an audio/visual device. The mounting system includes a first mounting portion configured to operatively connect to the audio/visual device, a second mounting portion configured to attach to the first mounting portion and to a mounting surface, and an adjustment mechanism operatively connecting the first mounting portion to the second mounting portion. The adjustment mechanism includes a housing with a bore formed therein, a clutch positioned within the housing, and a rotatable shaft positioned within the housing and being operatively connected to the first mounting portion, the shaft being configured to rotate within the bore relative to the housing. The shaft is rotatable within the bore in a first rotational direction through the clutch with a first torque, and the shaft is rotatable within the bore in a second rotational direction through the clutch with a second torque.

Another embodiment of the invention relates to an articulating mount that includes a first mounting portion configured to operatively connect to a device, an adjustment mechanism operatively connected to the first mounting portion, at least one articulation mechanism operatively connected to the adjustment mechanism and a second mounting portion. The adjustment mechanism includes a housing with a bore formed therein, a clutch positioned within the housing, and a rotatable positioned within the housing and being operatively connected to the first mounting portion, the shaft being configured to rotate within the bore relative to the housing. The at least one articulation mechanism includes an inner arm having a first end and a second end, and an outer arm having a first end operatively connected to the housing and a second end operatively connected to the second end of the inner arm. The second mounting portion is configured to attach to a mounting surface and is operatively connected to the first end of the inner arm. The shaft is rotatable within the bore in a first rotational direction through the clutch with a first torque, and the shaft is rotatable within the bore in a second rotational direction through the clutch with a second torque.

Yet another embodiment of the invention relates to an adjustment mechanism for use in a mounting system. The adjustment mechanism includes a housing with a bore formed therein, a rotatable shaft positioned within the housing and being configured to rotate within the bore relative to the housing, and a clutch positioned within the housing and being configured to influence the rotation of the shaft, wherein the clutch allows the shaft to rotate in a first rotational direction with a first torque, and wherein the clutch allows the shaft to rotate in a second rotational direction with a second torque.

### BRIEF DESCRIPTION OF THE DRAWINGS

FIG. 1 is a perspective view of an exemplary embodiment of a device mount.

FIG. 2 is a front plan view of the device mount of FIG. 1.

FIG. 3 is a rear plan view of the device mount of FIG. 1.

FIG. 4 is a top view of the device mount of FIG. 1.

FIG. 5 is a bottom view of the device mount of FIG. 1.

FIG. 6 is a right side view of the device mount of FIG. 1.

FIG. 7 is a left side view of the device mount of FIG. 1.

FIG. 8 is an exploded perspective view of an exemplary embodiment of an adjustment mechanism for use in the device mount, such as the device mount of FIG. 1.

FIG. 9 is a perspective view of the adjustment mechanism of FIG. 8 in an assembled state.

FIG. 10 is a front plan view of the adjustment mechanism of FIG. 8 in an assembled state.

FIG. 11 is a top view of the adjustment mechanism of FIG. 8 in an assembled state.

FIG. 12 is a rear plan view of the adjustment mechanism of FIG. 8 in an assembled state.

FIG. 13 is a is bottom view of the adjustment mechanism of FIG. 8 in an assembled state.

FIG. 14 is a right side view of the adjustment mechanism of FIG. 8 in an assembled state.

FIG. 15 is a left side view of the adjustment mechanism of FIG. 8 in an assembled state.

FIG. 16 is a perspective view of a housing portion of the adjustment mechanism of FIGS. 8-15.

FIG. 17 is a perspective view of a clutch spring of the adjustment mechanism of FIGS. 8-15.

FIG. 18 is a perspective view of a rotatable shaft of the adjustment mechanism of FIGS. 8-15.

FIG. 19 is a perspective view of another housing portion of in the adjustment mechanism of FIGS. 8-15.

FIG. 20 is a perspective view of another exemplary device mount within which the adjustment mechanism of FIGS. 8-15 may be installed.

FIG. 21 is a perspective view of yet another exemplary device mount within which the adjustment mechanism of FIGS. 8-15 may be installed.

FIG. 22 is a graph illustrating calculated torque values of a mounted device for an exemplary embodiment of a device mount, the graph showing weight of the mounted device with a center of mass provided at a given distance from the pivot center.

FIG. 23 is a graph illustrating calculated torque values of a mounted device for another exemplary embodiment of a device mount, the graph showing weight of the mounted device with a center of mass provided at a given distance from the pivot center.

### DETAILED DESCRIPTION

With general reference to the Figures, disclosed in the present application are various embodiments of device mounts that are configured to provide support and adjustability to a device, such as a display device. The device mounts include adjustment mechanisms that provide variable adjustment of the mounted device (e.g., display device) mounted relative to a fixing member or support, such as a wall, in which the device mount is attached thereto. The adjustment mechanisms allow the mounted devices to pivot about one or more pivot axes to provide variable adjustment of the relative position of the mounted device, such as for a customer to reposition the display device to improve visibility thereof. The adjustment mechanisms may include a clutch, for example, or a similar mechanism to allow rotation in a first direction about a pivot axis with a first torque and to allow rotation in a second direction about the pivot axis with a second torque.

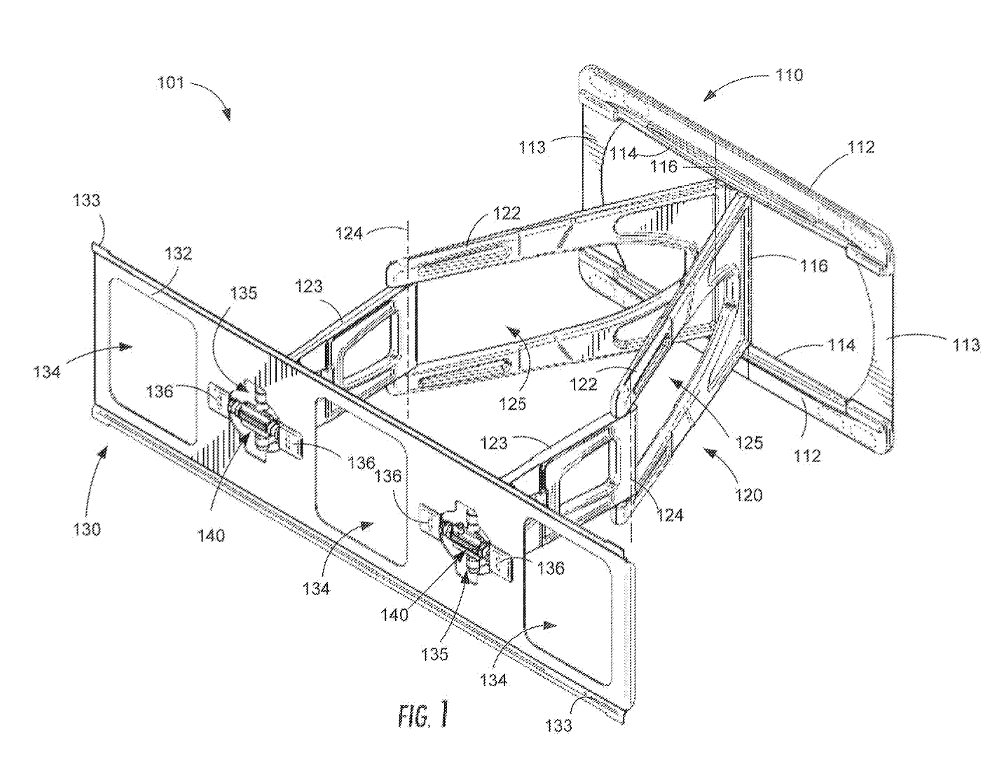

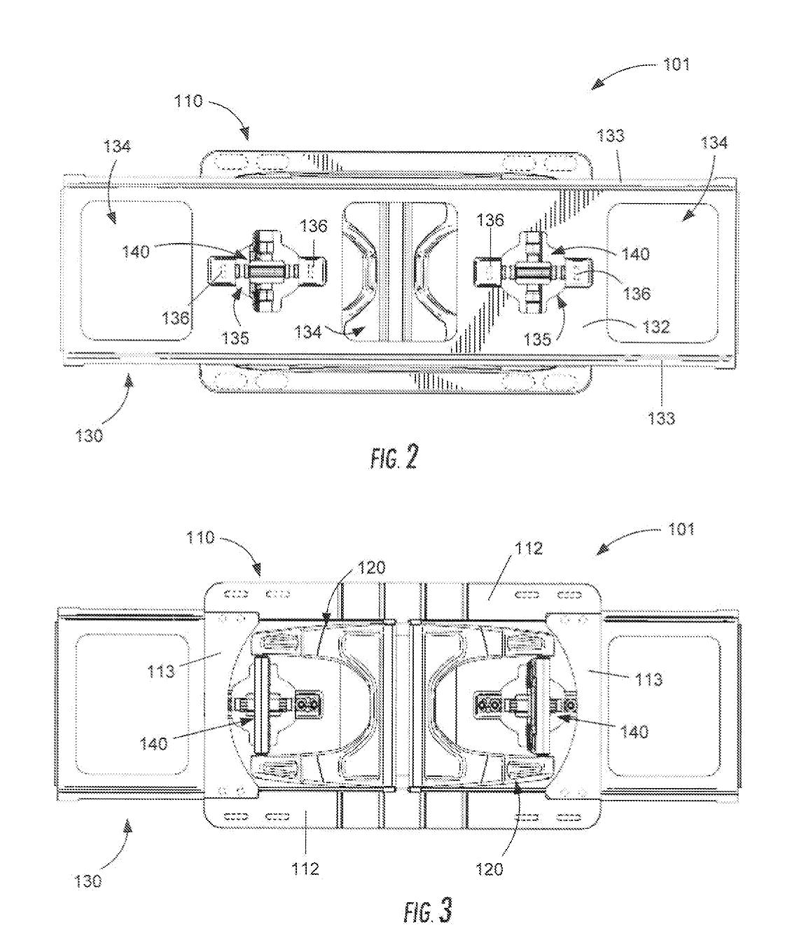

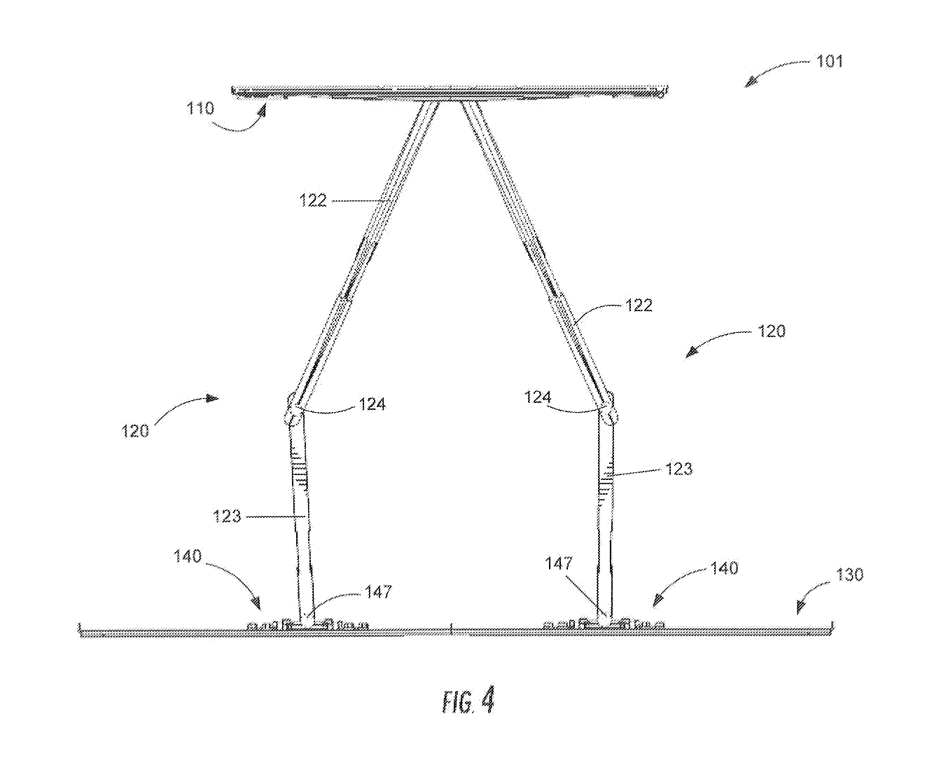

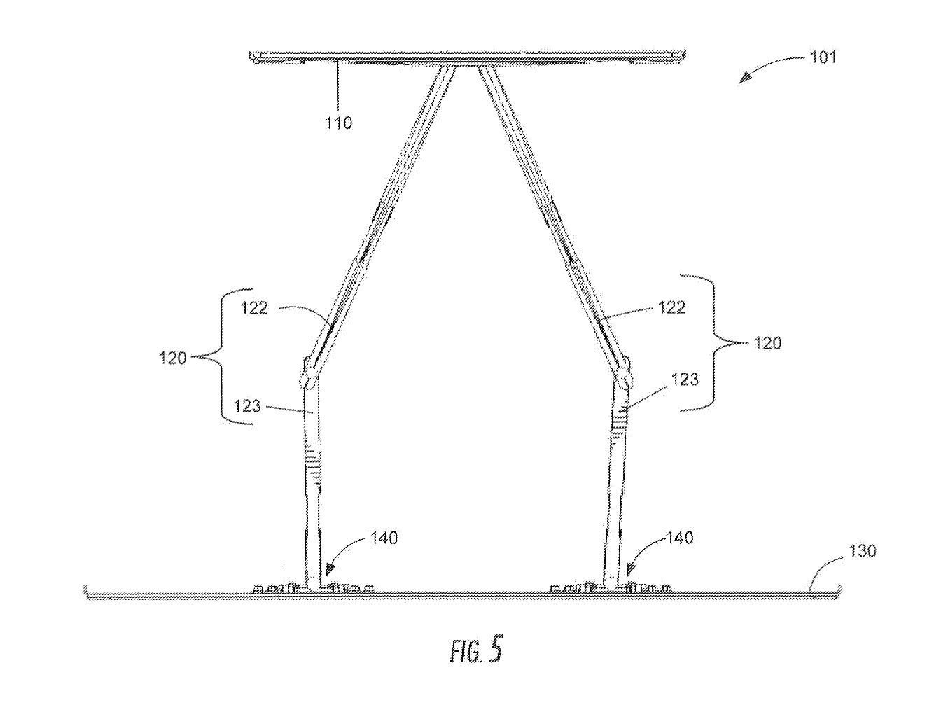

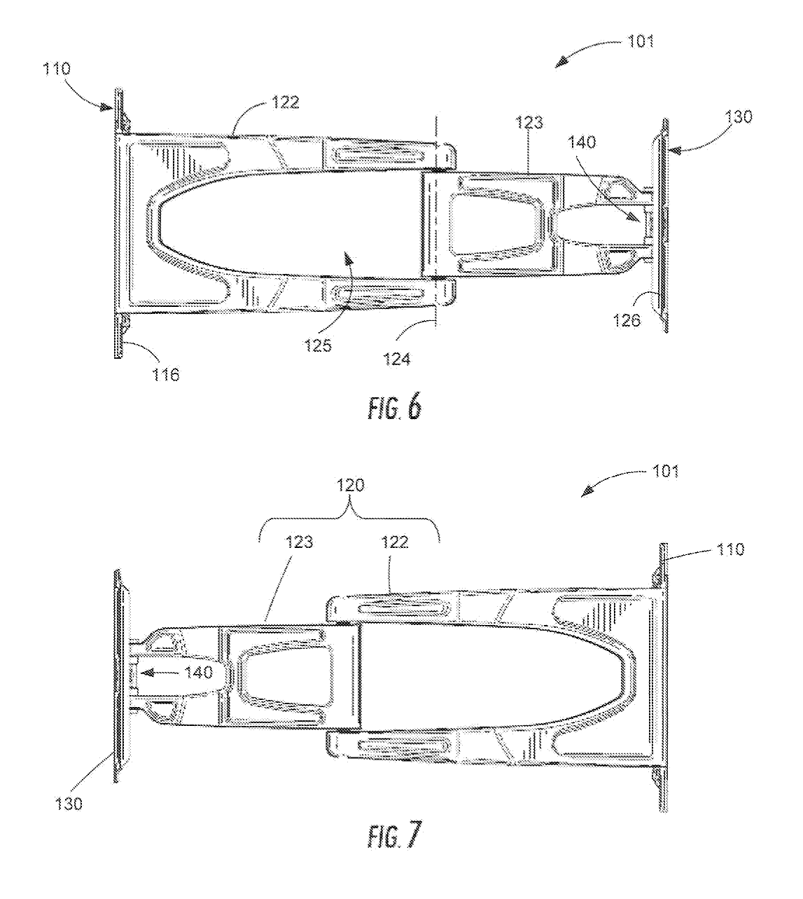

FIGS. 1-7 illustrate an exemplary embodiment of a device mount 101 that is configured to provide for the variable adjustment of a coupled device, such as a flat screen display device, relative to a fixing member, such as a wall. As shown in FIG. 1, the device mount 101 includes a surface mounting bracket 110, a pair of articulation mechanisms 120, a device mounting bracket 130, and a pair of adjustment mechanisms 140. The surface mounting bracket 110 affixes the device mount 101 to a fixing member, such as a wall, while the articulation mechanisms 120 are operatively connected to the surface mounting bracket 110. The adjustment mechanisms 140 are provided between and operatively connected to the articulation mechanisms 120 and the device mounting bracket 130, such that the articulation mechanisms 120 allow for articulation of the mounted device relative to the surface mounting bracket 110 and the adjustment mechanisms 140 allow for the variable adjustment of the mounted device relative to the orientation of the surface mounting bracket 110.

The surface mounting bracket 110 (e.g., the second mounting portion) of the device mount 101 is configured to affix the device mount 101 to an object or member that is configured to support the combined mass of the device mount 101 and the mounted device. Although FIG. 1 shows the surface mounting bracket 110 adapted for coupling the device mount 101 to a vertical wall, the surface mounting bracket 110 may be adapted to be coupled to any suitable fixture, such as a support or a free-standing member.

The surface mounting bracket 110 may include one or more brackets that are aligned in any suitable manner and coupled together through any suitable method, such as fasteners or welding. As shown in FIGS. 1 and 3, the surface mounting bracket 110 includes a pair of horizontal brackets 112 and a pair of vertical brackets 113. The pair of horizontal brackets 112 may be uniquely configured or may be similarly configured, such as being symmetrically opposite about a horizontal axis or plane. The pair of vertical brackets 113 may be uniquely configured or may be similarly configured, such as being symmetrically opposite about a vertical axis or plane. The ends of the pair of horizontal brackets 112 are coupled to the ends of the pair of vertical brackets 113, such that a spacing or gap is provided between the pairs of brackets, to thereby define a rectangular shaped surface mounting bracket 110.

The surface mounting bracket 110 includes holes or any suitable feature for coupling the device mount 101 to the fixing member. For example, the surface mounting bracket 110 may include slots that are configured to receive fasteners (e.g., bolts) to affix the surface mounting bracket 110 to the fixing member, while allowing for variation there between.

The surface mounting bracket 110 further includes features for coupling the articulation mechanisms 120 to the surface mounting bracket 110. For example, the horizontal bracket 112 includes a flange 114 that extends in a perpendicular direction from the surface of the horizontal bracket 112 that abuts (or is adjacent to) the fixing member. The flange 114 includes one or more than one holes or openings, which may be configured to receive another component, such as a pivot member that enables articulation of the articulation mechanism 120 relative to the surface mounting bracket 110. Each bracket 112 of the symmetrically configured pair of horizontal brackets 112 (e.g., upper and lower brackets) includes a hole that opposes a matching hole in the opposing bracket 112 to thereby define a pivot axis 116 for the pivot member to rotate about. Accordingly, for the device mount 101 having two (or more) articulation mechanisms 120, the flange 114 of each bracket 112 includes two (or more) holes that oppose two (or more) matching holes in the opposing bracket 112 to define two pivot axes 116, one for each articulation mechanism 120 to pivot about.

The articulation mechanism 120 operatively connects to the adjustment mechanism 140 and is configured to articulate the mounted device between a first or collapsed position and a second or extended position relative to the surface mounting bracket 110. As shown in FIGS. 1, 6, and 7, each articulation mechanism 120 includes an inner articulating arm 122 and an outer articulating arm 123. The inner articulating arm 122 is pivotally coupled to the surface mounting bracket 110, such that the inner articulating arm 122 pivots about the pivot axis 116 relative to the surface mounting bracket 110 a predetermined range of motion (e.g., 180 degrees). The outer articulating arm 123 is pivotally coupled to the inner articulating arm 122, such that the inner and outer articulating arms 122, 123 pivot relative to each other about a pivot axis 124 over a predetermined range of motion (e.g., 180 degrees). Alternatively, the outer articulating arm 123 and the inner articulating arm 122 may be configured to allow for 360 degrees of rotation relative to each other. As shown, the inner articulating arm 122 is configured as a C-shaped member that defines a void 125, in which the outer articulating arm 123 is configured to nest or reside within upon articulation, such as upon articulation to the collapsed position. The outer articulating arm 123 may have any suitable shape, such as a generally hollow rectangular shape having one or more support members. The shape and material of the articulating arms may be varied, such as to tailor the strength of the arms and articulation mechanism 120 based on the size of the device that is to be mounted to the device mount 101. The outer articulating arm 123 is also pivotally coupled to the adjustment mechanism 140, such that the adjustment mechanism 140 and/or the device mounting bracket 130 rotate or pivot about a pivot axis 126 relative to the outer articulating arm 123.

The articulation mechanism 120 is adapted to provide motion along a plane. For example, the articulation mechanism 120 may be configured to allow the device mounting bracket 130 and the coupled device to move relative to the surface mounting bracket 110, such as translate in a direction perpendicular to a plane defined by the fixing member that the surface mounting bracket 110 is coupled thereto. The surface mounting bracket 110 is configured to articulate from a collapsed position to an extended position, whereby there are an infinite number of intermediate positions between the collapsed and extended positions in which the surface mounting bracket 110 may be configured.

In the collapsed position, both the inner and outer articulating arms 122, 123 are positioned proximate to the surface mounting bracket 110, as well as to each other. The inner articulating arm 122 may be configured to nest within the outer articulating arm 123, such that both articulating arms 122, 123 may abut or be adjacent to the surface mounting bracket 110 in the collapsed position. Thus, when in the collapsed position, the device mount 101 is configured to have a low profile or minimized thickness (e.g., depth), whereby the device mounting bracket 130 is proximate to the surface mounting bracket 110.

In the extended position, the device mounting bracket 130 is moved away from the surface mounting bracket 110, such as by pivoting the inner and outer articulating arms 122, 123 until the inner articulating arm 122 is substantially in line with the outer articulating arm 123. In other words, when the device mount 101 is in the extended position the pivotally coupled inner and outer articulating arms 122, 123 are aligned to form a substantially similar plane relative to the surface mounting bracket 110 Thus, when in the extended position, the device mount 101 is configured to have a wide profile or maximized thickness (e.g., depth), whereby the device mounting bracket 130 is offset a distance from the surface mounting bracket 110. The offset distance is approximately equal to the combined lengths of the articulating arms and, therefore, can be varied by changing the corresponding lengths of the articulating arms.

The articulation mechanism 120 includes a first pivot member (e.g., an articulation shaft). For example, the first pivot member may pivotally couple the inner articulating arm 122 to the outer articulating arm 123, where the pivot member defines the pivot axis 124. The pivot member may be configured as a shaft having a body portion that engages the outer articulating arm 123, such as a bore provided therein. The pivot member may include two ends for engaging the inner articulating arm 122, with one end being provided on each of the opposing ends of the body, such as for each end to engage an opening or bore in one of the legs of the C-shaped inner articulating arm 122.

The articulation mechanism 120 also includes a second pivot member and a third pivot member. The second pivot member pivotally couples the inner articulating arm 122 to the surface mounting bracket 110 to thereby define the pivot axis 116. The second pivot member may include a body for engaging the inner articulating arm 122 and ends for engaging the horizontal brackets 112, such as the holes in the flanges 114 of the brackets 112. The third pivot member pivotally couples the outer articulating arm 123 to the adjustment mechanism 140 to thereby define the pivot axis 126. The third pivot member may include a body for engaging the adjustment mechanism 140 and ends for engaging the outer articulating arm 123.

The device mounting bracket 130 (e.g., the first mounting portion) is adapted to secure a device (e.g., a display device) to the device mount 101. For example, the device mounting bracket 130 may be coupled to the adjustment mechanism 140 of the device mount 101, whereby the position (e.g., orientation) of a secured display device is adjustable relative to the fixing member (and/or the surface mounting bracket 110) through articulation of the articulation mechanism 120 and/or through adjustment of the adjustment mechanism 140.

The device mounting bracket 130 includes a base 132 that is configured to receive the device. The device mounting bracket 130 may also include forms, flanges, ribs, or other structural members to improve the strength and rigidity of the device mounting bracket 130. As shown in FIG. 1, the device mounting bracket 130 includes upper and lower flanges 133 that extend the length of the base 132 to provide structural support. The device mounting bracket 130 may also include voids or lightening holes to reduce the mass of the device mounting bracket 130. The mass reduction voids may be varied in size and location, based on the desired mass and/or strength of the device mounting bracket 130. As shown in FIG. 1, the device mounting bracket 130 includes three lightening holes 134 provided in the base 132, where one hole 134 is located between the adjustment mechanisms 140 and the other two holes 134 are located outside of one of the adjustment mechanisms 140.

The device mounting bracket 130 also includes an aperture or hole 135 located proximate to where each of the adjustment mechanisms 140 are located, such as to provide a cut-out for a portion of each adjustment mechanism 140 to pass therein. This configuration allows for the adjustment mechanism 140 and base 132 of the device mounting bracket 130 to maintain a low profile (e.g., thinner width), which allows the device mount 101 to maintain an overall low profile, such as when configured in the collapsed position. The base 132 may be coupled to the adjustment mechanism 140 through fasteners (e.g., bolts, screws), welding, or any suitable method. The base 132 may also have a feature, such as a pocket 136 that is offset from the base 132, for receiving a portion of the adjustment mechanism 140. The offset pocket 136 helps to maintain the overall low profile of the device mount 101. As shown, the base 132 includes two pockets 136, where each pocket 136 includes one or more than one hole for receiving one or more than one fastener to couple the adjustment mechanism 140 and the device mounting bracket 130. The device mounting bracket 130 (e.g., the base 132) also includes an attachment feature that is configured to couple the device (e.g., display device) to the device mounting bracket 130. The attachment feature may be in the form of fasteners (e.g., bolts, screws), tabs that interlock with slots or apertures in the device, hooks, straps, or any suitable method that provides for selective coupling of two devices.

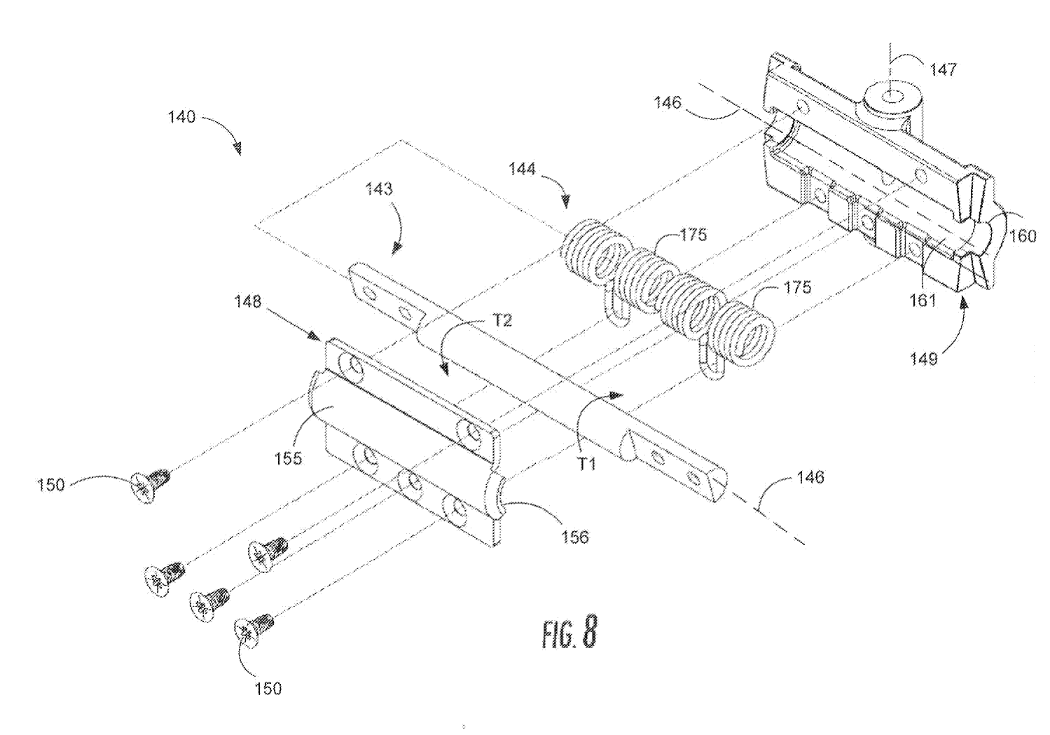

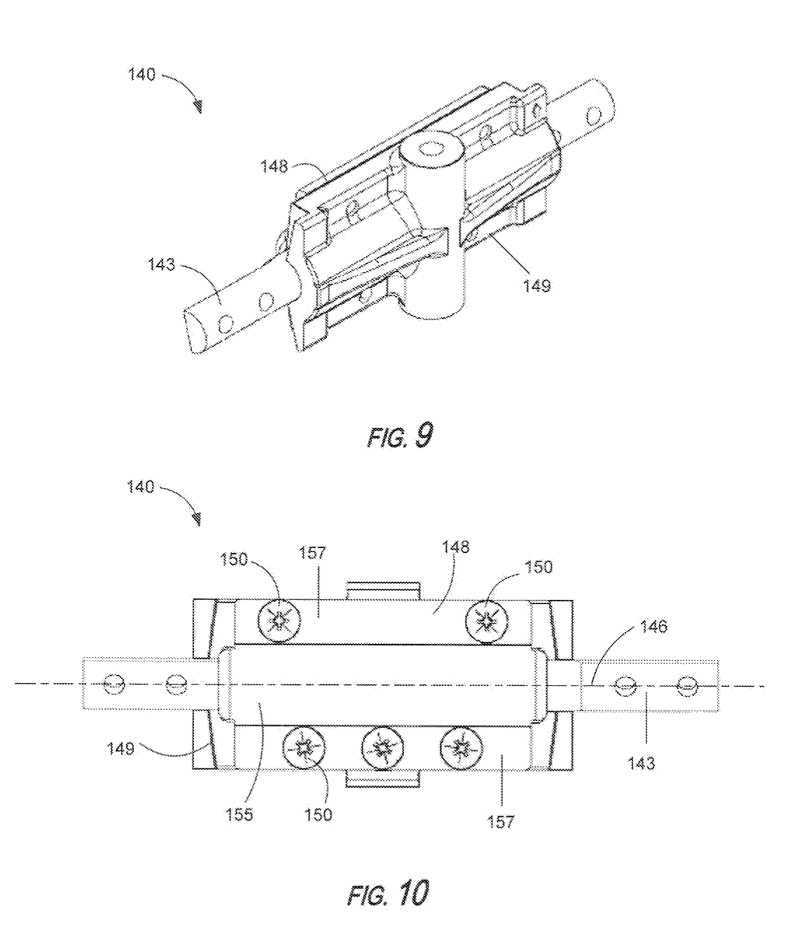

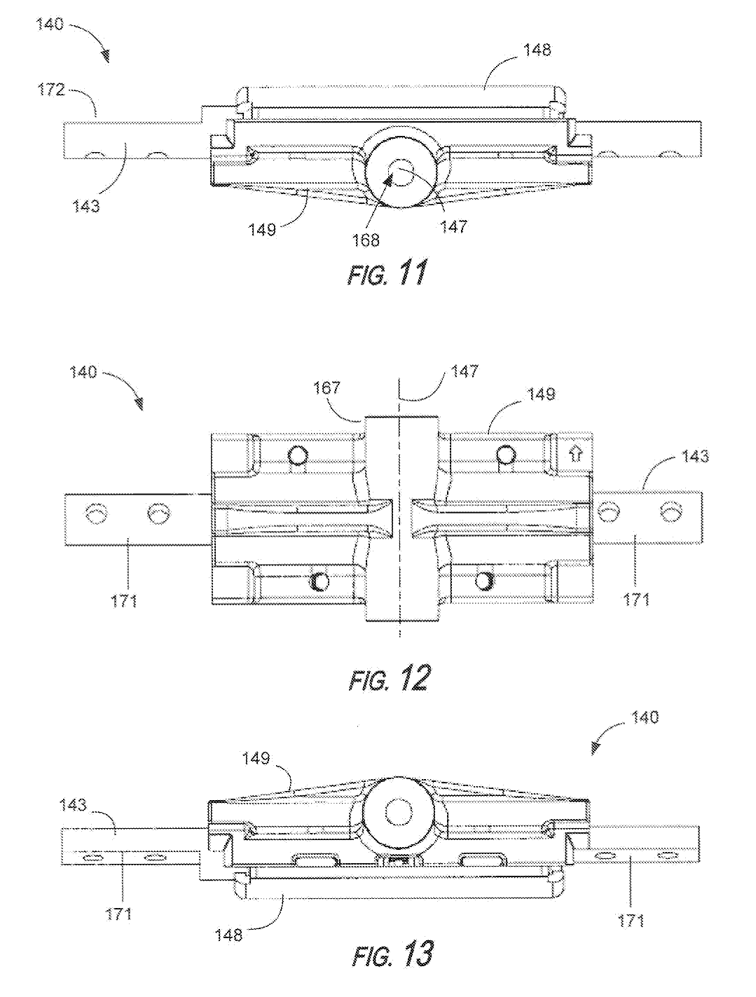

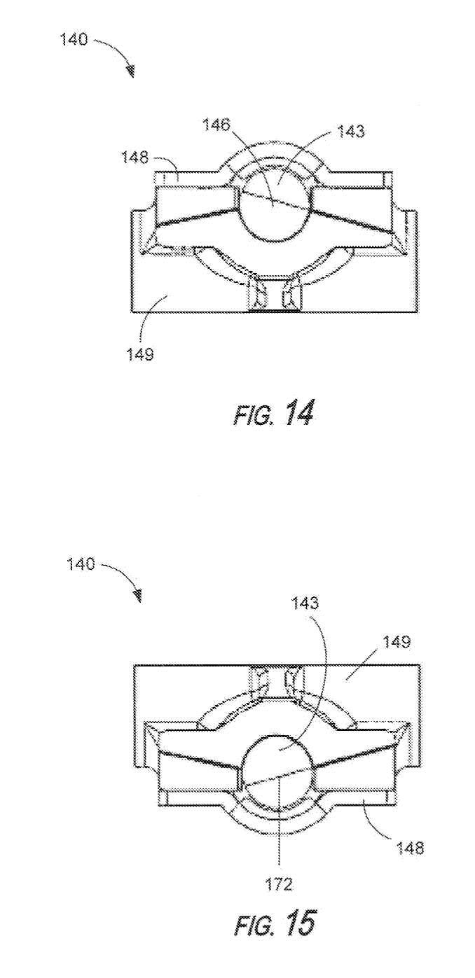

FIGS. 8-19 illustrate an exemplary embodiment of an adjustment mechanism 140. The adjustment mechanism 140 is configured to provide variable adjustment to a mounted device. The adjustment mechanism 140 operatively connects the device mounting bracket 130 to the surface mounting bracket 110. For example, the adjustment mechanism 140 may be configured to compensate for the weight of the mounted device by allowing the user to adjust (e.g., tilt) the mounted device about an axis of rotation by applying a similar force in both directions (e.g., clockwise, counter-clockwise). The adjustment mechanism 140 may include a clutch or clutch-type device to provide a similar adjustment force (e.g., torque) in both directions about a pivot axis.

As shown in FIG. 8, the adjustment mechanism 140 includes a housing 142, a rotatable shaft 143 (e.g., a journal), and a clutch 144. The housing 142 retains the rotatable shaft 143, such that rotatable shaft 143 is able to rotate or pivot about a first axis 146 relative to the housing 142. The housing 142 may also define a second axis of rotation 147 configured to be transverse to the first axis of rotation 146. The rotatable shaft 143 is operatively connected to the device mounting bracket 130, allowing the device mounting bracket 130 (and the device coupled thereto) to rotate about the first axis of rotation 146 relative to the housing 142. The clutch 144 is configured to influence the torque required to rotate the rotatable shaft 143 relative to the housing 142 about the first axis of rotation 146. For example, the clutch 144 may apply friction and/or torque, such as to the rotatable shaft 143, when the user rotates the mounted device and/or the device mounting bracket 130 in a first direction (e.g., a counter-clockwise rotational direction) about the first axis of rotation 146. The clutch may further be configured to not apply friction and/or torque, such as by allowing the rotatable shaft 143 to freely rotate relative to the housing 142, when the user rotates the mounted device and/or the device mounting bracket 130 in a second direction (e.g., a clockwise rotational direction) about the first axis of rotation 146.

The housing 142 includes a first housing portion 148 and second housing portion 149 that are configured to be coupled together through fasteners, such as the screws 150, to form a bearing surface 152 that defines a bore 153 for the rotatable shaft 143 to rotate therein. The first housing portion 148 includes a partial cylindrical portion 155 having an inner surface 156 that defines a portion of the bearing surface 152 and the bore 153. The cylindrical portion 155 extends in a generally horizontal direction, such that the bore 153 defines a horizontal axis of rotation. Accordingly, the horizontal axis of rotation of the bore 153 defines the first axis of rotation 146 that the rotatable shaft 143 rotates about. The first housing portion 148 also includes a mounting portion 157 for coupling the first housing portion 148 to the second housing portion 149. As shown in FIGS. 8 and 19, the first housing portion 148 includes upper and lower mounting portions 157, where the upper mounting portion 157 extends away from the cylindrical portion 155 in an upwardly direction and the lower mounting portion 157 extends away from the cylindrical portion 155 in a downwardly direction. The mounting portions 157 include a plurality of openings to receive fasteners, such as the screws 150, to couple the first housing portion 148 to the second housing portion 149.

The second housing portion 149 includes a partial cylindrical portion 160 having an inner surface 161 that defines a portion of the bearing surface 152 and the bore 153. The cylindrical portion 160 extends in a generally horizontal direction mirroring that of the cylindrical portion 155 of the first housing portion 148, such that the bore 153 defines a horizontal axis of rotation that defines the first axis of rotation 146 in which the rotatable shaft 143 rotates about. The second housing portion 149 also includes a mounting portion 163 for coupling the first housing portion 148 to the second housing portion 149. Thus, together the cylindrical portion 155 of the first housing portion 148 and the cylindrical portion 160 of the second housing portion 149 define the bore 153, where the inner surface 156 of the first housing portion 148 together with the inner surface 161 of the second housing portion 149 define the bearing surface 152.

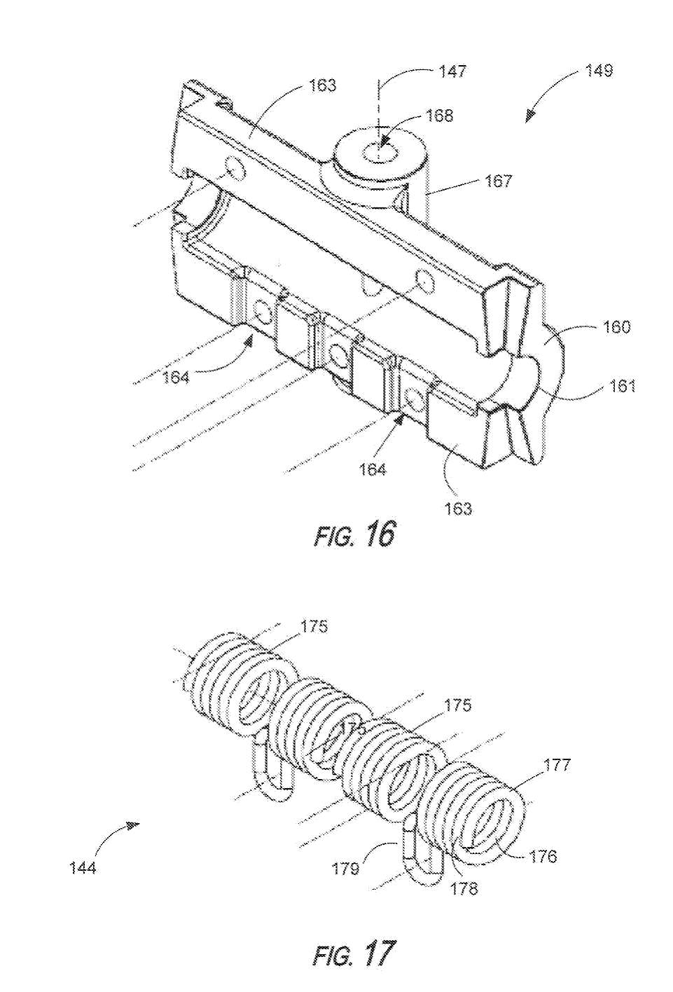

As shown in FIGS. 8 and 16, the second housing portion 149 includes upper and lower mounting portions 163, where the upper mounting portion 163 extends away from the cylindrical portion 160 in an upwardly direction and the lower mounting portion 163 extends away from the cylindrical portion 160 in a downwardly direction. The upper mounting portion 163 of the second housing portion 149 is configured to abut the upper mounting portion 157 of the first housing portion 148, and the lower mounting portion 163 of the second housing portion 149 is configured to abut the lower mounting portion 157 of the first housing portion 148. The mounting portions 163 include holes to receive fasteners, such as the screws 150, to couple the first housing portion 148 to the second housing portion 149. The second housing portion 149 (e.g., the mounting portions 163) may also include a recess 164 (e.g., cavity) configured to receive a portion of the clutch 144, such as to retain the portion within the recess 164 between the first and second housing portions 148, 149. As shown in FIG. 16, the second housing portion 149 includes a plurality of recesses 164 in the lower mounting portion 163 to thereby retain more than one portion of the clutch 144 therein.

The second housing portion 149 also includes a second cylindrical portion 167 having a second bore 168 to define a second axis of rotation 147. The second cylindrical portion 167 extends in a transverse direction relative to the first cylindrical portion 160, to thereby align the second bore 168 and second axis of rotation 147 perpendicular to the first bore 153 and the first axis of rotation 146. The second cylindrical portion 167 is configured to be coupled, such as through a pivot member (e.g., third pivot member), to the outer articulating arm 123, where the second housing portion 149 (and housing 142) rotates or tilts relative to the outer articulating arm 123 about the second axis of rotation 147.

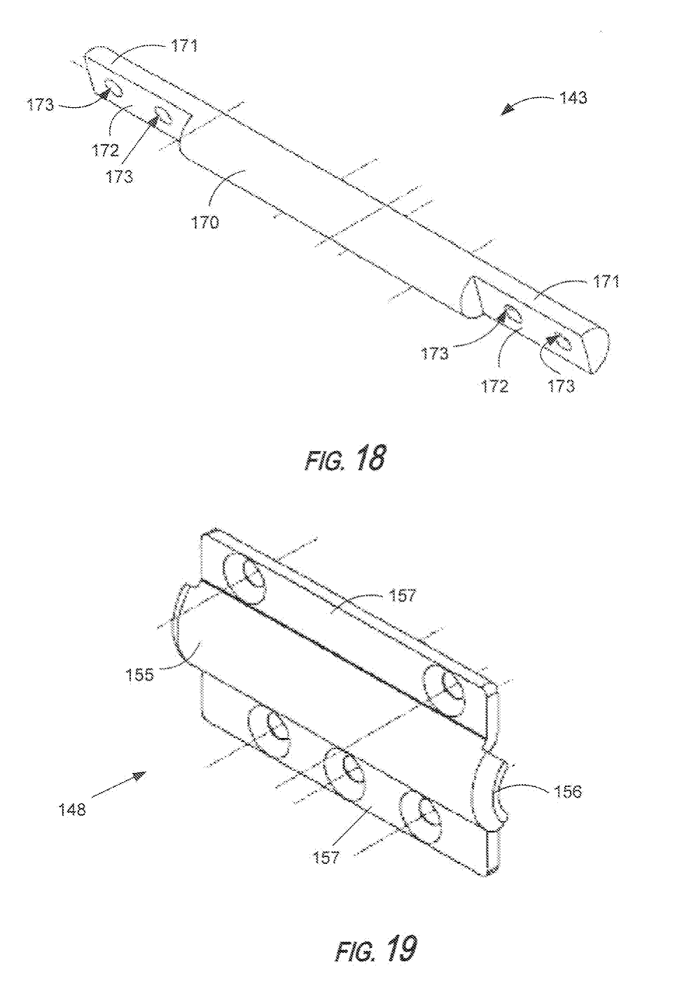

As shown in FIGS. 8 and 18, the rotatable shaft 143 (e.g., the journal) is configured to rotate within the bearing 152 about the first axis of rotation 146 relative to the housing 142. The shaft 143 is configured to rotate within the bearing surface 152 in a first direction, such as a counter-clockwise rotational direction, and in a second direction, such as a clockwise rotational direction, about the first axis of rotation 146 relative to the housing 142. The shaft 143 is rotatable within the bore 153 in the first rotational direction through the clutch 144 with a first torque, and the shaft 143 is rotatable within the bore 153 in the second rotational direction through the clutch 144 with a second torque. The first torque may be substantially equal to the second torque, or the torques may be different. The rotatable shaft 143 is also positioned within the housing 142 and is operatively connected to the device mounting bracket 130.

The shaft 143 includes a body 170 having a circular cross-section to provide for efficient rotation of the shaft 143 within the bearing surface 152. The shaft 143 also includes an end 171 that is configured to be coupled to the device mounting bracket 130 using any suitable method (e.g., fasteners, welding). As shown in FIG. 18, the shaft 143 includes two ends 171, where each end 171 is on an opposing side of the body 170. Each end 171 of the shaft 143 includes a flat portion 172 configured to abut the device mounting bracket 130, such as a pocket 136, when the shaft 143 is coupled to the device mounting bracket 130. The flat portion 172 is formed out the circular cross-section of the body 170 to thereby form a D-shaped end 171 where the circular periphery of the D-shape is concentric to and configured to have a similar diameter to the circular cross-section of the body 170. The end 171 also includes one or more than one opening or hole 173, such as to receive a fastener to couple the shaft 143 and the device mounting bracket 130. As shown in FIG. 18, each end 171 includes two holes 173, where each hole 173 is configured to receive a fastener to couple the shaft 143 and the device mounting bracket 130.

The clutch 144 is configured to influence the torque required to rotate the rotatable shaft 143 relative to the housing 142 about the first axis of rotation 146. The clutch 144 is positioned within the housing 142. As shown in FIG. 8, the clutch 144 is provided in the bore 153 between the rotatable shaft 143 and the bearing surface 152 of the housing 142. The clutch 144 includes one or more than one spring to influence the torque required to rotate the shaft 143 relative to the housing 142. As shown in FIGS. 8 and 17, the clutch 144 includes two coiled torsion springs 175 that are helical in shape having an inner diameter 176 and an outer diameter 177. The inner diameter 176 is configured to receive the shaft 143 and may include a predetermined amount of clearance between the inner diameter 176 and the outside surface of the shaft 143. The outer diameter 177 is configured to reside in the bore 153 and may include a predetermined amount of clearance between the outer diameter 177 and the bore 153.

The coil spring 175 includes an anti-rotation feature, such as to prohibit rotation of the spring 175 relative to the housing 142. As shown in FIG. 17, the anti-rotation feature is configured as a U-shaped portion 179 that extends away from the outer diameter 177 of the helical coil spring 175. The U-shaped portion 179 is part of the coil that forms the helical coil spring 175, and is configured to engage the recess 164 of the second housing portion 149 of the housing 142 to prevent rotation of the spring 175 relative to the housing 142. Alternatively, the end 178 of the spring 175 may include a flat portion that is configured to be the anti-rotation feature, where the end 178 may engage a recess 164 to prevent relative rotation between the spring 175 and the housing 142.

The clutch 144 is configured to apply friction and/or torque, such as to the rotatable shaft 143, when the user rotates the mounted device and/or the device mounting bracket 130 in a first direction about the first axis of rotation 146. The clutch 144 is also configured to not apply friction and/or torque (or a substantially reduced amount thereof), such as by allowing the rotatable shaft 143 to freely rotate relative to the housing 142, when the user rotates the mounted device and/or the device mounting bracket 130 in a second direction about the first axis of rotation 146. For example, the clutch 144 is configured to allow free rotation of the shaft 143 about the first axis of rotation 146 in the rotational direction T1, by not applying friction or a substantially reduced friction, and the clutch 144 is configured to apply a friction force or torque to the shaft 143 when the shaft 143 is rotated about the first axis of rotation 146 in the rotational direction T2.

The adjustment mechanism 140 may be configured such that the rotation of the shaft 143 in the first rotational direction causes the clutch 144 to increase the friction force applied to the shaft 143 to increase the first torque to overcome the force from gravity, such as acting to rotate an audio/visual device coupled to the device mounting bracket 130. The adjustment mechanism 140 may also be configured such that the rotation of the shaft 143 in the second rotational direction causes the clutch 144 to decrease the friction force applied to the shaft 143 to decrease the second torque.

When the user rotates the mounted device and/or the device mounting bracket 130 in a first direction (e.g., a downwardly direction) that corresponds to the shaft 143 rotating in the rotational direction T2 about the first axis of rotation 146 relative to the housing 142, the mass of the mounted device works for the user, since the force from gravity is in the direction of rotation. Accordingly, the clutch 144 is configured to apply a friction force (or torque) when the user rotates the mounted device in the rotational direction T2. The clutch 144 applies a frictional force or torque to the shaft 143, because when the shaft 143 is rotated in the rotational direction T2 relative to the spring 175 (and housing 142) about the first axis of rotation 146, the helical shaped coils of the spring 175 contract (e.g., decrease) bringing the inner diameter 176 of the spring 175 into contact (or greater contact) with the outside surface of the shaft 143 thereby generating friction between the contacting surfaces. In other words, the rotation of the shaft 143 in the rotational direction T2 relative to the clutch 144 operates to decrease the inner diameter 176 of the spring 175 to increase the friction force from the clutch 144 (i.e., between the spring 175 and the shaft 143). The clutch 144 may be configured with a predetermined amount of clearance between the shaft 143 and the inner diameter 176 of the spring 175 to allow for the friction force from the clutch 144 to be varied.

Conversely, when the user rotates the mounted device and/or the device mounting bracket 130 in a second direction (e.g., an upwardly direction) that corresponds to the shaft 143 rotating in the rotational direction T1 about the first axis of rotation 146 relative to the housing 142, the user has to overcome a force that is a function of the mass of the mounted device (and the device mounting bracket 130), since the user is working against or opposing gravity. Accordingly, the clutch 144 is configured to allow for free rotation by imparting no friction force (or a friction force at a reduced level) when the user rotates the mounted device in the rotational direction T1. The clutch 144 allows for free (or a reduced friction) rotation in the rotational direction T1, because the helical shaped coils of the spring 175 expand (e.g., increase) in diameter when the shaft 143 is rotated in the rotational direction T1 relative to the spring 175 (and housing 142) about the first axis of rotation 146. In other words, the rotation of the shaft 143 in the rotational direction T1 relative to the clutch 144 operates to increase the inner diameter 176 of the spring 175 to reduce the friction force from the clutch 144 (i.e., between the shaft 143 and spring 175) to allow for free (or a reduced friction) rotation of the shaft 143. The clutch 144 may be configured with a predetermined amount of clearance between the bore 153 of the housing 142 and the outer diameter 177 of the spring 175 to allow for expansion of the spring (i.e., an increase in the outer and inner diameters).

Thus, the clutch 144 of the adjustment mechanism 140 is configured to allow the user to apply a similar force or torque to rotate or tilt the device mount 101 in two opposing rotational directions, such as, for example, where the first direction is in a direction with gravity and the second direction is in a direction opposing gravity. This provides a constant or similar ergonomic feel to the operation of the device mount 101. However, it should be noted that the friction force or torque that the clutch 144 applies may be varied based on various parameters (e.g., the number and configuration of the springs 175, the clearances, etc.). Accordingly, the clutch 144 of the adjustment mechanism 140 may be varied to tailor the force or torque required to rotate or pivot the mounted device about the first axis of rotation 146, such that the force required to move the mounted device in a first direction may be different than the force required to move the mounted device in a second direction.

Although the adjustment mechanism 140 is shown having a single clutch 144 or torque influencing device, the adjustment mechanism 140 may be configured to include more than one clutch 144. For example, an adjustment mechanism of a device mount may include a first clutch for influencing the torque required to move a mounted device about a first axis of rotation and a second clutch for influencing the torque required to move the mounted device about a second axis of rotation.

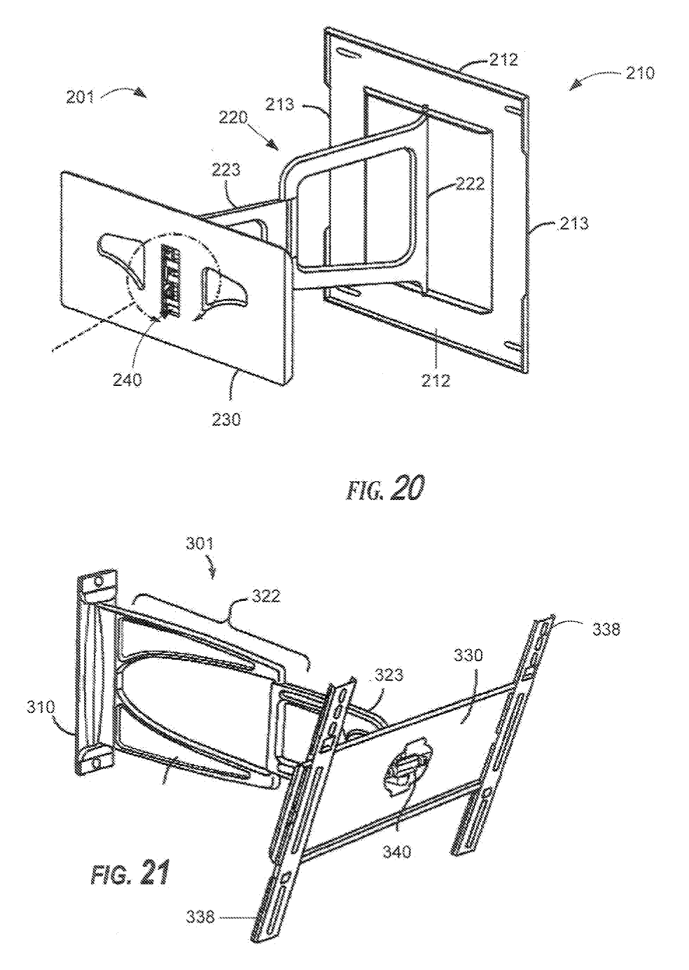

FIGS. 20 and 21 illustrate other exemplary embodiments of device mounts 201, 301 that are configured to provide for the variable adjustment of a coupled device, such as a flat screen display device, relative to a fixing member, through adjustment mechanisms 240, 340. As shown in FIG. 20, the device mount 201 includes a surface mounting bracket 210 having a pair of horizontal brackets 212 and a pair of vertical brackets 213, an articulation mechanism 220 having an inner arm 222 and an outer arm 223, a device mounting bracket 230 configured to receive a device (e.g., a display device), and an adjustment mechanism 240 provided between the articulation mechanism 220 and the device mounting bracket 230. The adjustment mechanism 240 is configured to allow a device coupled to the device mounting bracket 230 to rotate or tilt relative to the articulation mechanism 220, as discussed above. As shown in FIG. 21, the device mount 301 includes a surface mounting bracket 310 for mounting to fixing member, an articulation mechanism 320 having an inner arm 322 and an outer arm 323, a device mounting bracket 330 configured to receive a device (e.g., a display device), and an adjustment mechanism 340 provided between the articulation mechanism 320 and the device mounting bracket 330. The adjustment mechanism 340 is configured to allow a device coupled to the device mounting bracket 330 to rotate or tilt relative to the articulation mechanism 320 and the fixing member, as discussed above. According to another exemplary embodiment, the device mount includes a surface bracket, a device mounting plate, and an adjustment mechanism. In other words, the device mounts, as disclosed herein, may be configured without an articulation mechanism or any number of articulation mechanisms.

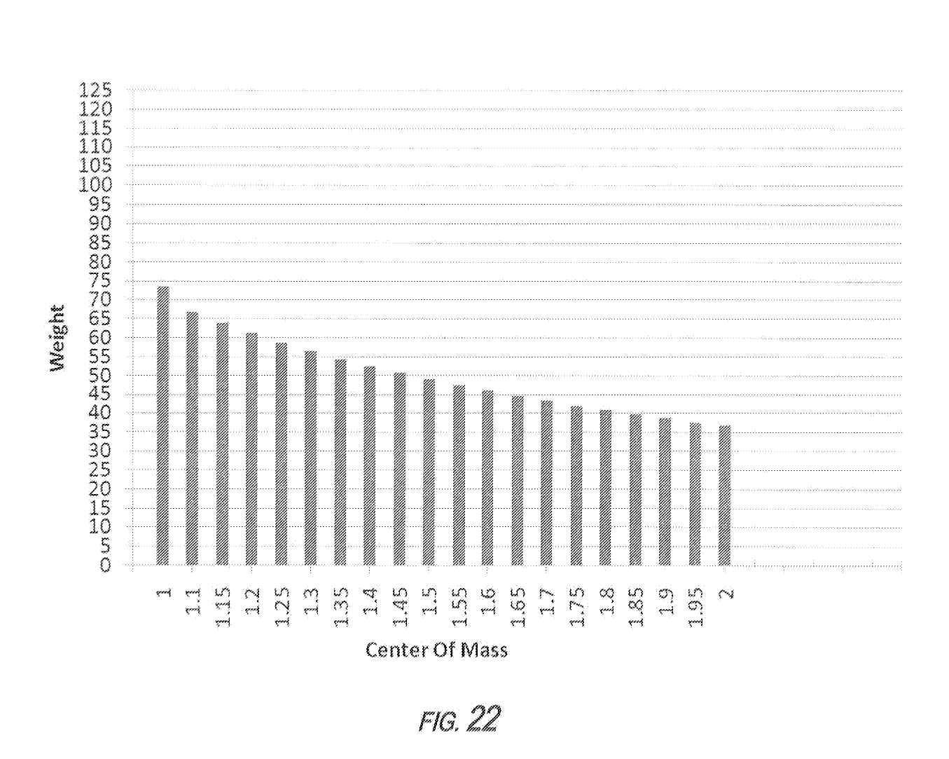

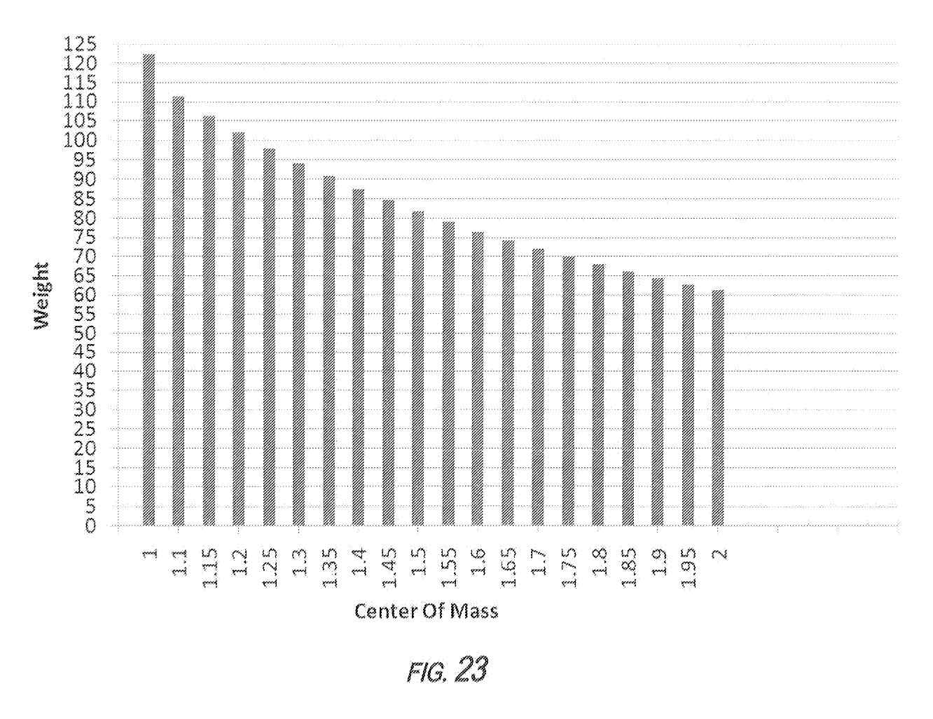

FIGS. 22 and 23 are graphs that illustrate calculated torque values of a mounted device coupled to exemplary embodiments of a device mount, as disclosed herein. On the x-axis is shown the distance in inches (in.) from the axis of rotation (e.g., of the adjustment mechanism) to the center of mass of the mounted device (e.g., display device). On the y-axis is shown the weight in pounds (lbs.) of the mounted device. Thus, the torque that the adjustment mechanism imparts to influence the torque required to rotate the mounted device about a rotatable shaft relative to a housing about a first axis of rotation may be calculated from the weight and distance values provided in the graphs.

FIG. 22 is a graph illustrating calculated torque values of a mounted device for an exemplary embodiment of a device mount, the graph showing weight of the mounted device with a center of mass provided at a given distance from the pivot center. For example, FIG. 22 represents the calculated torque that an adjustment mechanism having a clutch with a single spring may impart to influence the torque required to rotate the mounted device about a rotatable shaft relative to a housing about a first axis of rotation, such as in the rotational direction opposing gravity. As illustrated, the spring of the clutch may be configured to support a mounted device having a weight of about 74 lbs. and a center of mass located at about 1.0 in. from the pivot or axis of rotation.

FIG. 23 is a graph illustrating calculated torque values of a mounted device for another exemplary embodiment of a device mount, the graph showing weight of the mounted device with a center of mass provided at a given distance from the pivot center. For example, FIG. 23 represents the calculated torque that an adjustment mechanism having a clutch with two springs may impart to influence the torque required to rotate the mounted device about a rotatable shaft relative to a housing about a first axis of rotation, such as in the rotational direction opposing gravity. As illustrated, the springs of the clutch may be configured to support a mounted device having a weight of about 123 lbs. and a center of mass located at about 1.0 in. from the pivot or axis of rotation.

It should be noted that FIGS. 22 and 23 represent exemplary embodiments, and are not meant as limitations on the device mounts as disclosed herein. For example, the device mount may include an adjustment mechanism having a clutch that includes any number of springs. Additionally, the springs used in the clutches of the adjustment mechanisms may be configured having varying torques, which may differ from those shown or described herein. It should be noted that the clutches (e.g., springs) of the adjustment mechanisms, as disclosed herein, may be varied based on the mass of the mounted device and/or the distance between the center of mass of the mounted device and the pivot center of the adjustment mechanism to thereby tailor the performance of the device mount accordingly.

It should be noted that the device mount having an adjustment mechanism may include any number of articulation mechanisms, in which the number of articulation mechanisms may be based upon the size (length, width, mass) of the device that is being mounted to the device mount, and that the device mounts disclosed in the present application are not intended as limitations, but are merely exemplary embodiments.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

References herein to the positions of elements (e.g., “top,” “bottom,” “above,” “below,” etc.) are merely used to describe the orientation of various elements in the Figures. It should be noted that the orientation of various elements may differ according to other exemplary embodiments, and that such variations are intended to be encompassed by the present disclosure.

It is important to note that the construction and arrangement of the device mounts and the adjustment mechanisms, as shown in the various exemplary embodiments, are illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter described herein. For example, elements shown as integrally formed may be constructed of multiple parts or elements, the position of elements may be reversed or otherwise varied, and the nature or number of discrete elements or positions may be altered or varied. The order or sequence of any process or method steps may be varied or re-sequenced according to alternative embodiments. Other substitutions, modifications, changes and omissions may also be made in the design, operating conditions and arrangement of the various exemplary embodiments without departing from the scope of the present invention.

What is claimed is:

1. A mounting system for supporting an audio/visual device, comprising:
a first mounting portion configured to operatively connect to the audio/visual device;
a second mounting portion configured to attach to the first mounting portion and to a mounting surface; and
an adjustment mechanism operatively connecting the first mounting portion to the second mounting portion, the adjustment mechanism including:
a housing with a bore formed therein,
a clutch positioned within the housing, and
a rotatable shaft positioned within the housing and being operatively connected to the first mounting portion, the shaft being configured to rotate within the bore relative to the housing; and
wherein the shaft is rotatable within the bore in a first rotational direction through the clutch with a first torque, and wherein the shaft is rotatable within the bore in a second rotational direction through the clutch with a second torque.

2. The mounting system of claim 1, wherein the first torque is substantially equal to the second torque.

3. The mounting system of claim 1, wherein the clutch includes a coil spring having an inner diameter that encircles at least a portion of the shaft.

4. The mounting system of claim 3, wherein the rotation of the shaft in the first rotational direction induces the inner diameter of the coil spring to expand, thereby increasing the clearance between the inner diameter and the shaft.

5. The mounting system of claim 3, wherein the rotation of the shaft in the second rotational direction induces the inner diameter of the coil spring to contract, thereby contacting the shaft to impart a friction force into the shaft.

6. The mounting system of claim 3, wherein the coil spring includes an anti-rotation feature that is configured to engage a recess in the housing to prevent rotation of the spring relative to the housing.

7. The mounting system of claim 2, wherein the rotation of the shaft in the first rotational direction causes the clutch to increase the friction force applied to the shaft to increase the first torque to overcome the force from gravity acting to rotate the audio/visual device in the first rotational direction, and wherein the rotation of the shaft in the second rotational direction causes the clutch to decrease the friction force applied to the shaft to decrease the second torque.

8. An articulating mount, comprising:
a first mounting portion configured to operatively connect to a device;
an adjustment mechanism operatively connected to the first mounting portion and including:
a housing with a bore formed therein,
a clutch positioned within the housing, and
a rotatable positioned within the housing and being operatively connected to the first mounting portion, the shaft being configured to rotate within the bore relative to the housing;
at least one articulation mechanism operatively connected to the adjustment mechanism and including:
an inner arm having a first end and a second end, and
an outer arm having a first end operatively connected to the housing and a second end operatively connected to the second end of the inner arm; and
a second mounting portion configured to attach to a mounting surface and operatively connected to the first end of the inner arm;
wherein the shaft is rotatable within the bore in a first rotational direction through the clutch with a first torque, and wherein the shaft is rotatable within the bore in a second rotational direction through the clutch with a second torque.

9. The articulating mount of claim 8, wherein the first torque is substantially equal to the second torque.

10. The articulating mount of claim 8, wherein the clutch includes a helical coil spring having an inner diameter that encircles a portion of the shaft.

11. The articulating mount of claim 10, wherein the rotation of the shaft in the first rotational direction induces the inner diameter of the spring to expand thereby increasing the clearance between the inner diameter and the shaft and wherein the rotation of the shaft in the second rotational direction induces the inner diameter of the spring to contract thereby contacting the shaft to impart a friction force into the shaft.

12. The articulating mount of claim 10, wherein the spring includes an anti-rotation feature to prevent rotation of the spring relative to the housing.

13. The articulating mount of claim 8, wherein the rotation of the shaft in the first rotational direction causes the clutch to increase the friction force applied to the shaft to increase the first torque to overcome the force from gravity acting to rotate the device in the first rotational direction, and wherein the rotation of the shaft in the second rotational direction causes the clutch to decrease the friction force applied to the shaft to decrease the second torque.

14. An adjustment mechanism for use in a mounting system, comprising:
a housing with a bore formed therein;
a rotatable shaft positioned within the housing and being configured to rotate within the bore relative to the housing; and
a clutch positioned within the housing and being configured to influence the rotation of the shaft;
wherein the clutch allows the shaft to rotate in a first rotational direction with a first torque, and wherein the clutch allows the shaft to rotate in a second rotational direction with a second torque.

15. The articulating mount of claim 14, wherein the first torque is substantially equal to the second torque.

16. The articulating mount of claim 14, wherein the clutch includes a helical coil spring having an inner diameter that encircles a portion of the shaft.

17. The articulating mount of claim 16, wherein the rotation of the shaft in the first rotational direction induces the inner diameter of the spring to expand thereby increasing the clearance between the inner diameter and the shaft.

18. The articulating mount of claim 16, wherein the rotation of the shaft in the second rotational direction induces the inner diameter of the spring to contract thereby contacting the shaft to impart a friction force into the shaft.

19. The articulating mount of claim 16, wherein the spring includes an anti-rotation feature that is configured to engage a recess in the housing to prevent rotation of the spring relative to the housing.

20. The articulating mount of claim 14, wherein the rotation of the shaft in the first rotational direction causes the clutch to increase the friction force applied to the shaft to increase the first torque, and wherein the rotation of the shaft in the second rotational direction causes the clutch to decrease the friction force applied to the shaft to decrease the second torque.
